(19) United States
(12) Patent Application Publication
(10) Pub. No.: US 2003/0149928 A1
(43) Pub. Date: Aug. 7, 2003

(54) Turbo-code decoder

(76) Inventors: Yeun-Renn Ting, Taoyuan Hsien (TW); Erl-Huei Lu, Taoyuan Hsien (TW); Kuang-Shyr Wu, Taoyuan Hsien (TW); Gau-Joe Lin, Taoyuan Hsien (TW)

Correspondence Address: J.C. Patents, Inc., 4 Venture, Suite 250, Irvine, CA, 92618, US

(21) Appl. No.: 10/072,319

(22) Filed: Feb. 7, 2002

(51) Int. Cl. H03M 13/00

(52) U.S. Cl. 714/755

(57) ABSTRACT

The present invention provides a turbo-code decoder that adopts the parallel and systolic array VLSI structure design. Since the output of previous level can be used as the input of next level. So the advantages of the parallel and the pipeline calculation are totally achieved. The latency is only N+M+2 units of time, the latency is shorten to as about ⅕ comparing to the conventional sequential calculation structure that takes 5*(N+M) units of time. The decoding throughput is about 5*(N+M) times higher than the conventional decoder. Although the quantity of the circuit gate is about 5*(N+M) times higher than the conventional decoder. However, the VLSI techniques had been progressively improved nowadays, thus the hardware complexity is easy to overcome. Devoting the hardware cost to get the higher speed will be a changeless trend.

### BACKGROUND OF THE INVENTION

1. Field of Invention

The present invention generally relates to a decoder, and more particularly, to a fast turbo-code decoder. The decoder is designed to use the systolic array very large scaled integrated (VLSI) circuits; the output of previous level can be used as the input of next level. Thus, the advantages of the parallel and the pipeline calculation are totally achieved. The decoding speed has improved manifestly comparing to the calculation time of the conventional decoder. The speed has about 5*(N+M) times faster than the conventional decoder, wherein, N stands for the block length, and M stands for register size.

2. Description of Related Art

The error control coding is widely used in the communication system and the computer media storage. Berrou, Glavieux and Thitimajshima first proposed the turbo-code whose error-correcting capability nears to the Shannon limited error-correcting in 1993 (C. Berrou, A. Glavieux, and P. Thitimajshima, “Near Shannon Limited Error-correcting Coding and Decoding: Turbo-codes (1),” in Proc. ICC'93, May, 1993). Since the excellence of the error-correcting capability, the turbo-code is widely applied in the general communication system such as the CDMA transmission system. Whereas, if the block length of the conventional decoding algorithm is too small, the error-correcting capability is not good, wherein the block length is for transmission. On the other hand, if the block length of transmission is too large, for a communication system needs the real time processing, the decoding delay is too large to tolerant. Therefore, it is important to solve this problem to fulfill the requirement of the current high-speed communication.

### SUMMARY OF THE INVENTION

To solve the problem mentioned above and to increase the computing speed and thus to increase the throughput. The present invention provides a structure design using the parallel and systolic array VLSI.

The structure design adopting the parallel and systolic array VLSI mentioned above, wherein the decoder is designed to use the systolic array VLSI circuits. Since the output of previous level can be used as the input of next level. So the advantages of the parallel and the pipeline calculation are totally achieved. The latency is only N+M+2 units of time, the latency is shorten to as about ⅕ comparing to the conventional sequential calculation structure that takes 5*(N+M) units of time. The decoding throughput is about 5*(N+M) times higher than the conventional decoder. Although the quantity of the circuit gate is about 5*(N+M) times higher than the conventional decoder. However, the VLSI techniques had been progressively improved nowadays, thus the hardware complexity is easy to overcome. Devoting the hardware cost to get the higher speed will be a changeless trend.

In order to achieve the objective mentioned above, the present invention uses a parallel and systolic array VLSI structure design to provide a turbo-code decoder for the communication system. The decoder comprises a serial-to-parallel output unit and a plurality of parallel decoding units. Wherein, the serial-to-parallel output unit receives a serial input signal, converts it and outputs a parallel signal. The parallel decoding units mentioned above are serially connected to form a plurality of levels. The first level parallel decoding unit receives the parallel signal that is output from the serial-to-parallel output unit. The output from the first level parallel decoding unit is sent to the second level parallel decoding unit, with certain sequence, the parallel signal passes through the parallel decoding units for decoding process.

The turbo-code decoder mentioned above, wherein, each parallel decoding unit receives an extrinsic parameter when processing the decoding process, to be the signal that is after the decoding process from the parallel decoding unit, and sends the extrinsic parameter to the next level of the parallel decoding unit.

The turbo-code decoder mentioned above, wherein, the extrinsic parameter is obtained from a deinterleaving operation. The extrinsic parameter of the first level parallel decoding unit is L_{a0,k}=(0, 0 . . . , 0), where k=1, 2, . . . , N, N is the block length of the turbo-code.

The turbo-code decoder mentioned above, wherein, the serial input signals are r_{1s,k}, r_{1p,k}, and r_{2p,k} messages of the turbo-code, whereas k=1, 2, . . . , N, N is the block length of the turbo-code.

The turbo-code decoder mentioned above, wherein, the serial-to-parallel output unit receives the r_{1s,k}, r_{1p,k}, and r_{2p,k}, wherein, the subscript K=0, 1, . . . , N+M−1 represents the whole block and end message. M stands for register size of the turbo-code decoder. The serial-to-parallel output unit coverts the received r_{1s,k}, r_{1p,k}, and r_{2p,k} messages and outputs the results to the first level parallel decoding unit in parallel. The first level parallel decoding unit also receives an extrinsic parameter L_{a,k} at the same time. The L_{a,k} is the parameter that is obtained via a deinterleaving operation on the previous level extrinsic parameter Λ(dₖ). The initial value of the first level decoding unit extrinsic parameter is set as L_{a0,k}=(0, 0 . . . , 0), a first level extrinsic parameter L_{a1,k} is generated via the first level parallel decoding unit. And makes the message r_{1s,k}, r_{1p,k} and r_{2p,k} pass through sequentially to be the input of next level.

The turbo-code decoder mentioned above, wherein, the parallel decoding unit comprises a first decoder, a second decoder, an interleaving unit, and a deinterleaving unit. Wherein, the first decoder receives the r_{1s,k}, r_{1p,k} messages and the extrinsic parameter L_{a,k}. The second decoder receives the r_{2p,k} message and the extrinsic parameter L_{a,k}. The interleaving unit is allocated between the first decoder and the second decoder, receives the output of the first decoder. The deinterleaving unit is connected to the second decoder, alternately outputs the output of the first decoder and the second decoder.

The turbo-code decoder mentioned above, wherein, the first decoder of the parallel decoding units constitutes a systolic array VLSI circuits structure.

The turbo-code decoder mentioned above, wherein, the systolic array VLSI circuits is composed of N+M units of the module C, A, B, D, and E. Wherein, the module C receives L_{a1,k}, r_{1s,k} and r_{1p,k}, and outputs rₖ⁽¹⁾(m) and rₖ⁽⁰⁾(m). Module A calculates a forward recursive probability parameter αₖ. Module B calculates a backward recursive probability parameter βₖ. Module D adopts (N+M) units of parallel calculation to obtain the Λ(dₖ) after the calculation of the αₖ, βₖ, and γₖ⁽ⁱ⁾ are finished. Module E outputs the value of the calculation from the module D, K=0, 1, . . . , N+M−1.

The turbo-code decoder mentioned above, wherein, the value of the Λ(dₖ) is calculated according to a MAP algorithm and following equation:

$$Λ ( {d}_{k} ) = log \frac{{\sum }_{m} {\sum }_{{m}^{′}} {γ}_{k}^{( 1 )} ( {m}^{′} , m ) \cdot {α}_{k - 1} ( {m}^{′} ) \cdot {β}_{k} ( m )}{{\sum }_{m} {\sum }_{{m}^{′}} {γ}_{k}^{( 0 )} ( {m}^{′} , m ) \cdot {α}_{k - 1} ( {m}^{′} ) \cdot {β}_{k} ( m )}$$

Wherein, αₖ is the forward recursive probability parameter, βₖ is the backward recursive probability parameter, γₖ⁽ⁱ⁾ is a branch probability parameter.

The turbo-code decoder mentioned above, wherein, the forward recursive probability parameter αₖ is obtained from the calculation of the previous parameter αₖ₋₁ and the branch probability parameter γₖ⁽ⁱ⁾, the equation is as follows:

$${α}_{k} ( m ) = \frac{{\sum }_{{m}^{′}} {{\sum }^{1}}_{i = 0} {γ}_{k}^{( i )} ( {m}^{′} , m ) \cdot {α}_{k - 1} ( {m}^{′} )}{{\sum }_{m} {\sum }_{{m}^{′}} {\sum }_{i = 0}^{1} {γ}_{k}^{( i )} ( {m}^{′} , m ) \cdot {α}_{k - 1} ( {m}^{′} )}$$

The turbo-code decoder mentioned above, wherein, the backward recursive probability parameter βₖ is obtained from the calculation of the next parameter βₖ₊₁ and the branch probability parameter γₖ⁽ⁱ⁾, the equation is as follows:

$${β}_{k} ( m ) = \frac{{\sum }_{{m}^{′}} {{\sum }^{1}}_{i = 0} {γ}_{k + 1}^{( i )} ( {m}^{′} , m ) \cdot {β}_{k + 1} ( {m}^{′} )}{{\sum }_{m} {\sum }_{{m}^{′}} {\sum }_{i = 0}^{1} {γ}_{k + 1}^{( i )} ( {m}^{′} , m ) \cdot {β}_{k + 1} ( {m}^{′} )}$$

The turbo-code decoder mentioned above, wherein, the branch probability parameter γₖ⁽ⁱ⁾ is obtained from following equation according to the MAP algorithm:

γₖ⁽ⁱ⁾(m′,m)=p(γ_{1s,k}|dₖ=i,sₖ=m,sₖ₋₁=m′)·p(r_{1s,k}|dₖ=i,sₖ=m,sₖ₋₁=m′)·q(dₖ=i|sₖ=m,sₖ₋₁=m′)·Pr{sₖ=m|sₖ₋₁=m′}

Wherein whether the probability parameter q(dₖ=i|sₖ=m,sₖ₋₁=m′) is 0 or 1 depends on the input bit dₖ=i is 0 or 1 combines the probability of the state m′ to the state m.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1 schematically shows a turbo-code encoder comprising of two parallel RSC encoders;

FIG. 2 schematically shows the decoding structure of the turbo-code;

FIG. 3 schematically shows the structure of the P levels parallel decoding unit (Level 1, Level 2, . . . , Level P);

FIG. 4 schematically shows the structure of the first level decoding unit of the parallel decoding units in FIG. 3;

FIG. 5 schematically shows the structure of the systolic array VLSI that is composed of the first level decoding unit of the parallel decoding unit in FIG. 4;

FIG. 6 schematically shows the structure of the simplified modules, data streams, and the latches of the parallel decoding units in FIG. 3 when N=4 and M=3;

FIG. 7 schematically shows the calculation structure of the branch probability parameter γₖ⁽ⁱ⁾(m′, m);

FIG. 8 schematically shows the structure of module A for calculating αₖ;

FIG. 9 schematically shows the structure of module B for calculating βₖ;

FIG. 10 schematically shows the structure of module D for calculating Λ(dₖ);

FIG. 11 schematically shows the structure of the calculation submodule L (using analog circuit);

FIG. 12 schematically shows the structure of the fast RSC encoder, wherein, G_{b}=1011, G_{d}=1010;

FIG. 13 schematically shows the trellis diagram;

FIG. 14 schematically shows the detail structure of module A (wherein the submodule L is designed as the digital circuit);

FIG. 15 schematically shows the detail structure of module D;

FIG. 16 schematically shows the latency for accomplishing a message having a block size length; and

FIG. 17 schematically shows the comparison of the bit error rate, wherein, the iterative decoding number P=6, code ratio R=1/3, register size M=3, generator parameter G_{b}=1011, G_{d}=1110, the 256*256 random interleaving method is adopted by the first decoder and the second decoder.

### DESCRIPTION OF THE PREFERRED EMBODIMENTS

The present invention provides a structure design adopting the parallel and systolic array VLSI. The structure design adopting the parallel and systolic array VLSI mentioned above, wherein the decoder is designed to use the systolic array VLSI circuits. Since the output of previous level can be used as the input of next level. So the advantages of the parallel and the pipeline calculation are totally achieved. The latency is only N+M+2 units of time, the latency is shorten to as about ⅕ comparing to the conventional sequential calculation structure that takes 5*(N+M) units of time. The decoding throughput is about 5*(N+M) times higher than the conventional decoder. Although the quantity of the circuit gate is about 5*(N+M) times higher than the conventional decoder. However, the VLSI techniques had been progressively improved nowadays, thus the hardware complexity is easy to overcome. Devoting the hardware cost to get the higher speed will be a changeless trend.

Berrou, Glavieux and Thitimajshima first proposed the turbo-code whose error-correcting capability nears to the Shannon limited error-correcting in 1993 (C. Berrou, A. Glavieux, and P. Thitimajshima, “Near Shannon Limited Error-correcting Coding and Decoding: Turbo-codes (1),” in Proc. ICC'93, May, 1993). The encoding structure comprises two parallel recursive systematic convolution encoder (hereafter abbreviated as RSC). The important characteristics are (1) Two convolution codes with the same structure encode in parallel, thus the receiving end is able to decode the message repeatedly; (2) To increase the minimum distance between two encoding codes by using the non-uniform random interleaving (S. Benedetto and G. Montorsi: “Role of Recursive Convolutional Codes in Turbo Codes,” Electron. Lett., Vol.31, No.11, pp. 858-859, 1995); and (3) Soft-in Soft-out decoding.

Because the characteristics mentioned above, the capability of the error-correcting appears equal and excellent. Due to the excellence of the error-correcting capability, the turbo-code is widely applied in the general communication system such as the CDMA transmission system (J. Blaanz, P. Jung, and M. Na B han, “Realistic Simulations of CDMA Mobile Radio Systems Using Joint Detection and Coherent Receiver Antenna Diversity,” IEEE third International Symposium on Spread Spectrum Techniques and Applications, Oulu Finland, 1994).

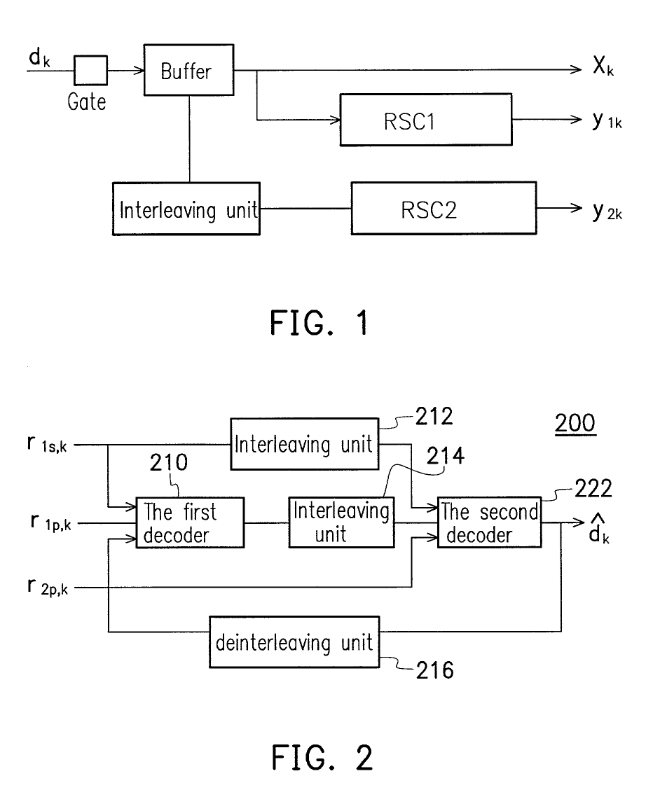

Referring to FIG. 1, it schematically shows a turbo-code encoder comprising of two parallel RSC encoders. The input bit sequence is represented as d=(d₁, d₂, d₃, . . . , dₖ, . . . , d_{N}), where dₖ is the input bit of the encoder at time k, k is from 1 to N, N is the block size. The output of the encoder at time k is represented as cₖ=(Xₖ,y₁ₖ,y₂ₖ). Since the encoder is systematic, so xₖ=dₖ, the surplus code output is represented as y₁ₖ, y₂ₖ. The decoding structure of the turbo-code is shown in FIG. 2. The decoder 200 comprises two recursive decoding units 210 and 220; two recursive decoding units 210 and 220 are connected in interleaving and deinterleaving unit as shown as the 212, 214 and 216 in the diagram.

It is assuming that the Gaussian noise is the noise used in the communication channel. It is further assuming that the noise of each transmission symbol is an independent noise, the expectation value is 0, and the variant is N₀/2. Using the binary modulation, if the input bit dₖ is 0, the modulation is −1.0; if the input bit dₖ is 1, the modulation is +1.0. Therefore, the sequence of the receiving vector R is represented as R=(r₁, r₂, r₃, . . . , rₖ, . . . , r_{N}), the kth symbol is represented as

rₖ=(r_{1s,k}, r_{1p,k}, r_{2p,k})=(2xₖ−1+n_{1s,k}, 2y₁ₖ−1+n_{1p,k}, 2y₂ₖ−1+n_{2p,k})

Wherein, n_{1s,k}, n_{1p,k}, and n_{2p,k} is the noise of the channel r₁ₛ, r₁ₚ, r₂ₚ at time k respectively, and they are independent each other. The detail of the Maximum A Posteriori (hereafter abbreviated as MAP) algorithm proposed by BCJR (L. Bahl, J. Cocke, F. Jelinek, and J. Raviv, “Optimal Decoding of Linear Codes for Minimizing Symbol Error Rate,” IEEE Tran. I. T., Vol.20, pp.284-287, March 1974) is not superfluously described here. Herein, only describe the result of the MAP algorithm. The objective of the MAP algorithm is to calculate whether the A Posterioi Probability (hereafter abbreviated as APP) of each input bit dₖ is the ratio of 1 or 0. Wherein, k=0, 1, 2, . . . , N−1. From the derivation result of the turbo-code having the error-correcting capability nears to the Shannon limited error-correcting proposed by Berrou, Glavieux and Thitimajshima mentioned above, the following equation is obtained:

$$Λ ( {d}_{k} ) = log \frac{{\sum }_{m} {\sum }_{{m}^{′}} {γ}_{k}^{( 1 )} ( {m}^{′} , m ) \cdot {α}_{k - 1} ( {m}^{′} ) \cdot {β}_{k} ( m )}{{\sum }_{m} {\sum }_{{m}^{′}} {γ}_{k}^{( 0 )} ( {m}^{′} , m ) \cdot {α}_{k - 1} ( {m}^{′} ) \cdot {β}_{k} ( m )} \qquad ( 1 )$$

Wherein, αₖ is the forward recursive probability parameter, βₖ is the backward recursive probability parameter, γₖ⁽ⁱ⁾ is the branch probability parameter. As we can see from the name, the forward recursive probability parameter αₖ can be obtained from the calculation of the previous parameter αₖ₋₁ and the branch probability parameter γₖ⁽ⁱ⁾, the equation is as follows:

$${α}_{k} ( m ) = \frac{{\sum }_{{m}^{′}} {{\sum }^{1}}_{i = 0} {γ}_{k}^{( i )} ( {m}^{′} , m ) \cdot {α}_{k - 1} ( {m}^{′} )}{{\sum }_{m} {\sum }_{{m}^{′}} {\sum }_{i = 0}^{1} {γ}_{k}^{( i )} ( {m}^{′} , m ) \cdot {α}_{k - 1} ( {m}^{′} )} \qquad ( 2 )$$

The backward recursive probability parameter βₖ can be obtained from the calculation of the next parameter βₖ₊₁ and the branch probability parameter γₖ₊₁⁽ⁱ⁾, the equation is as follows:

$${β}_{k} ( m ) = \frac{{\sum }_{{m}^{′}} {{\sum }^{1}}_{i = 0} {γ}_{k + 1}^{( i )} ( {m}^{′} , m ) \cdot {β}_{k + 1} ( {m}^{′} )}{{\sum }_{m} {\sum }_{{m}^{′}} {\sum }_{i = 0}^{1} {γ}_{k + 1}^{( i )} ( {m}^{′} , m ) \cdot {β}_{k + 1} ( {m}^{′} )} \qquad ( 3 )$$

The branch probability parameter γₖ⁽ⁱ⁾ is obtained from following equation according to the MAP algorithm:

γₖ⁽ⁱ⁾(m′,m)=p(γ_{1s,k}|dₖ=i,sₖ=m,sₖ₋₁=m′)·p(r_{1s,k}|dₖ=i,sₖ=m,sₖ₋₁=m′)·q(dₖ=i|sₖ=m,sₖ₋₁=m′)·Pr{sₖ=m|sₖ₋₁=m′} (4)

Wherein, whether the probability parameter q(dₖ=i|sₖ=m,sₖ₋₁=m′) is 0 or 1 depends on the input bit dₖ=i is 0 or 1 combines the probability of the state m′ to the state m.

In a sequential calculation decoder, it is assuming that each Λ(dₖ) in equation (1) needs a unit of time, wherein, K is from 0 to N+M−1, N stands for the block length of the transmission, and M stands for the register size of the decoder. It is further assuming that αₖ, βₖ, and γₖ⁽ⁱ⁾ in equation (2), (3), and (4) needs a unit of time respectively, wherein, i=0 or 1. Therefore, the first level decoder needs 5*(N+M) units of time. According to the decoding algorithm such as the Viterbi algorithm (A. J. Viterbi, “Error Bound for Convolutional Codes and an Asymptotically Optimum Decoding Algorithm,” IEEE Trans. Inform. Theorem, vol.IT-13, pp.260-269 April 1967)(A. J. Viterbi and J. K. Omura, “Principles of digital communication and coding,” New York: MacGraw-Hill, 1979) or the BCJR algorithm mentioned above, if N is too small, the error-correcting capability is not good. However, if N is too big, for a communication system needs the real time processing, the decoding delay is too big to tolerant.

As mentioned in the previous paragraph, currently the decoding algorithm is used to decide the value of Λ(dₖ) in equation (1), if Λ(dₖ)>0, dₖ=1, otherwise, dₖ=0. To calculate each Λ(dₖ) in equation (1), the αₖ, βₖ, and γₖ⁽ⁱ⁾ in equation (2), (3), and (4) must be calculated first. For a sequential calculation decoder, it needs 5*(N+M) units of time (G. Masera, G. Piccinini, M. R. Roch, nad M. Zqmboni, “VLSI Architectures for Turbo Codes,” IEEE Trans. On VLSI Systems, vol.7, no.3, pp. 369-379, September 1999).

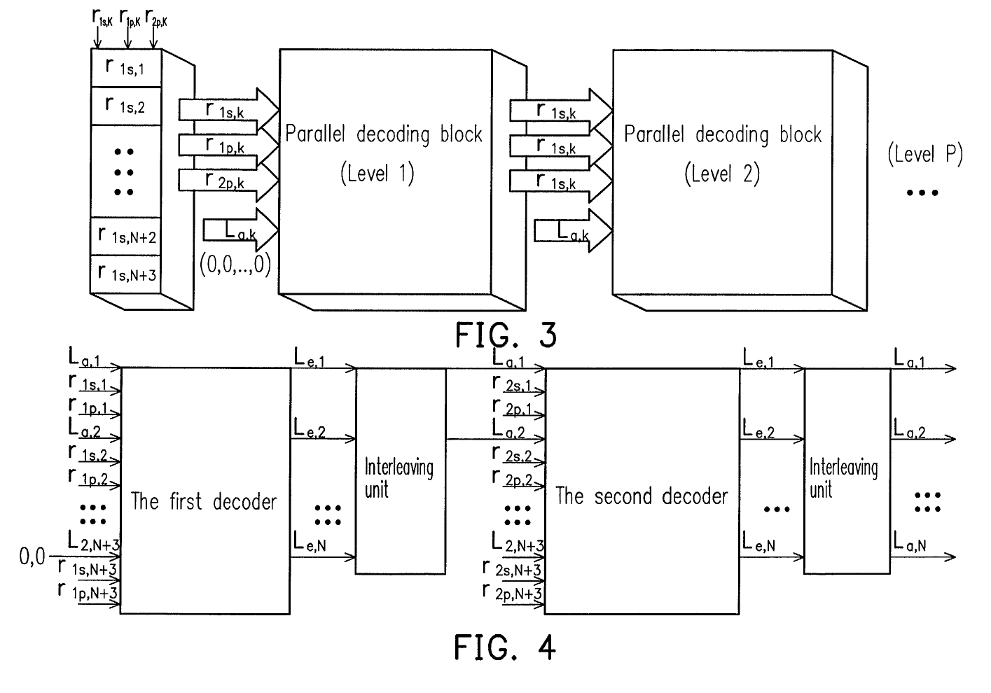

In order to increase the calculation speed and thus to increase the throughput. A preferred embodiment of the present invention adopts the parallel and systolic array VLSI structure design. The whole decoder circuit is composed of P levels parallel decoding units. The structure is shown in FIG. 3. There is a serial in parallel out unit before the first level to receive the message r_{1s,k}, r_{1p,k} and r_{2p,k} wherein, the subscript K=0, 1, . . . , N+M−1 represents the whole block and end message. The output is sent to the first level decoding unit, the other input of the first level decoding unit is L_{a,k}, herein, the L_{a,k} is the parameter obtained via the deinterleaving on the previous level extrinsic parameter Λ(dₖ), the initial value of the 0 th level decoding unit extrinsic parameter is set as L_{a0,k}=(0, 0 . . . , 0). The first level extrinsic parameter L_{a1,k} is generated via the first level decoding unit, and the message r_{1s,k}, r_{1p,k}, and r_{2p,k} sequentially pass through to be the input of next level.

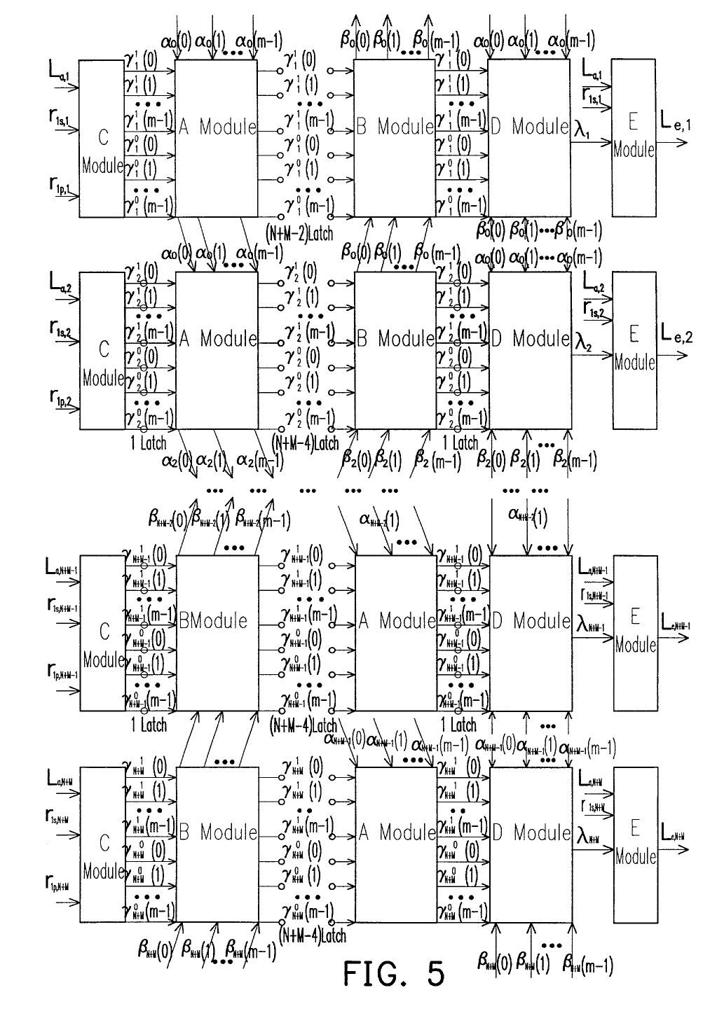

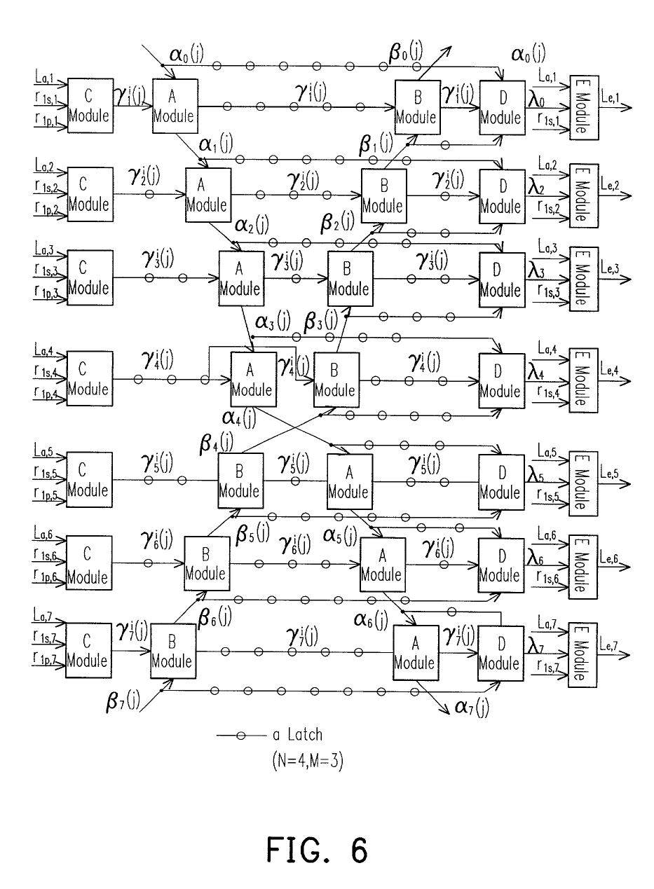

Each level of the decoding unit comprises two decoders. These two decoders are the first decoder and the second decoder as shown in FIG. 4, wherein, the structure of the first decoder is similar to the second decoder's. The whole systolic array VLSI structure is shown in FIG. 5. Wherein, N and M can be adjusted according to the design requirement. For easy to describe, the block length N=4 and register size M=3 are used as an example. FIG. 6 schematically shows the structure of the simplified modules, data streams, and the latches. It is apparent for those who skilled in the art that even the embodiment is used as an example in the present invention, the embodiment will not limit the apply range of the present invention.

According to the literature (I. L. Turner, “A Modified BAHL Algorithm for Recursive System Convolutional Codes on Rayleigh Fading Channels,” IEEE 49th Vehicular Technology Conference, pp.75-76 vol. 1, 1999), the apriori probability of the input bit dₖ calculated by the previous level decoder is represented as

$$\begin{matrix}Pr \{ {s}_{k} = m \vert {s}_{k - 1} = m \} = \frac{{e}^{L ( {d}_{K} )}}{1 + {e}^{L ( {d}_{K} )}} , if q ( {d}_{k} = 1 \vert {s}_{k} = m , {s}_{k - 1} = {m}^{′} ) = 1 & ( 5 ) \\ Pr \{ {s}_{k} = m \vert {s}_{k - 1} = m \} = \frac{{e}^{L ( {d}_{K} )}}{1 + {e}^{L ( {d}_{K} )}} = \frac{1}{1 + {e}^{L ( {d}_{K} )}} , if q ( {d}_{k} = 0 \vert {s}_{k} = m , {s}_{k - 1} = {m}^{′} ) = 1 & ( 6 )\end{matrix}$$

Wherein, L(dₖ) is the log likelihood ratio (LLR) extrinsic parameter calculated from the message bit dₖ by the previous level decoder. It is assumed in a AWGN channel, well than, the partial probability of the equation (4) is calculated as follows:

$$\begin{matrix}p ( {r}_{1 s , k} \vert {d}_{k} = i , {s}_{k} = m , {s}_{k - 1} = {m}^{′} ) = \frac{1}{\sqrt{2 π} {σ}_{r1s}} exp [ \frac{- {( {r}_{1 s , k} - {μ}_{r1s} )}^{2}}{2 {σ}_{r1s}^{2}} ] & ( 7 ) \\ p ( {r}_{1 p , k} \vert {d}_{k} = i , {s}_{k} = m , {s}_{k - 1} = {m}^{′} ) = \frac{1}{\sqrt{2 π} {σ}_{r1p}} exp [ \frac{- {( {r}_{1 p , k} - {μ}_{r1p} ( {m}^{′} , m ) )}^{2}}{2 {σ}_{r1p}^{2}} ] & ( 8 )\end{matrix}$$

Wherein, μᵣ₁ₛ and μᵣ₁ₚ(m′,m) is the expectation value of r₁ₛ and r₁ₚ respectively. Thereinto, μᵣ₁ₛ depends on the input bit, and μᵣ₁ₚ(m′,m) depends on the input bit and also impacted by the previous state and current state. σᵣ₁ₛ² and σᵣ₁ₚ² is the variant of the r₁ₛ and r₁ₚ respectively. It is assumed that the variant of r₁ₛ and r₁ₚ are the same. Therefore, the above two equations can be multiplied and consolidated as follows:

$$p ( {r}_{1 s , k} \vert {d}_{k} = i , {s}_{k} = m , {s}_{k - 1} = {m}^{′} ) \cdot p ( {r}_{1 p , k} \vert {d}_{k} = i , {s}_{k} = m , {s}_{k - 1} = {m}^{′} ) = \frac{1}{2 {πσ}^{2}} exp [ \frac{- 1}{2} \cdot \frac{{( {r}_{1 s , k} - {μ}_{r1s} )}^{2} + {( {r}_{1 p , k} - {μ}_{r1p} ( {m}^{′} , m ) )}^{2}}{{σ}^{2}} ] \qquad ( 9 )$$

For a discrete memory-less gauss channel, the branch probability parameter γₖ¹ or γₖ⁰ for input bit is 1 or 0 can be calculated from the equation (4), (5), (6), and (9) as follows:

$$\begin{matrix}{γ}_{k}^{( 1 )} ( {m}^{′} , m ) = \frac{1}{2 {πσ}^{2}} exp [ \frac{- 1}{2} \cdot \frac{{( {r}_{1 s , k} - 1 )}^{2} + {( {r}_{1 p , k} - {μ}_{r1p} ( {m}^{′} , m ) )}^{2}}{{σ}^{2}} ] \cdot \frac{{e}^{L ( {d}_{K} )}}{1 + {e}^{L ( {d}_{K} )}} & ( 10 ) \\ {γ}_{k}^{( 0 )} ( {m}^{′} , m ) = \frac{1}{2 {πσ}^{2}} exp [ \frac{- 1}{2} \cdot \frac{{( {r}_{1 s , k} + 1 )}^{2} + {( {r}_{1 p , k} - {μ}_{r1p} ( {m}^{′} , m ) )}^{2}}{{σ}^{2}} ] \cdot \frac{1}{1 + {e}^{L ( {d}_{K} )}} & ( 11 )\end{matrix}$$

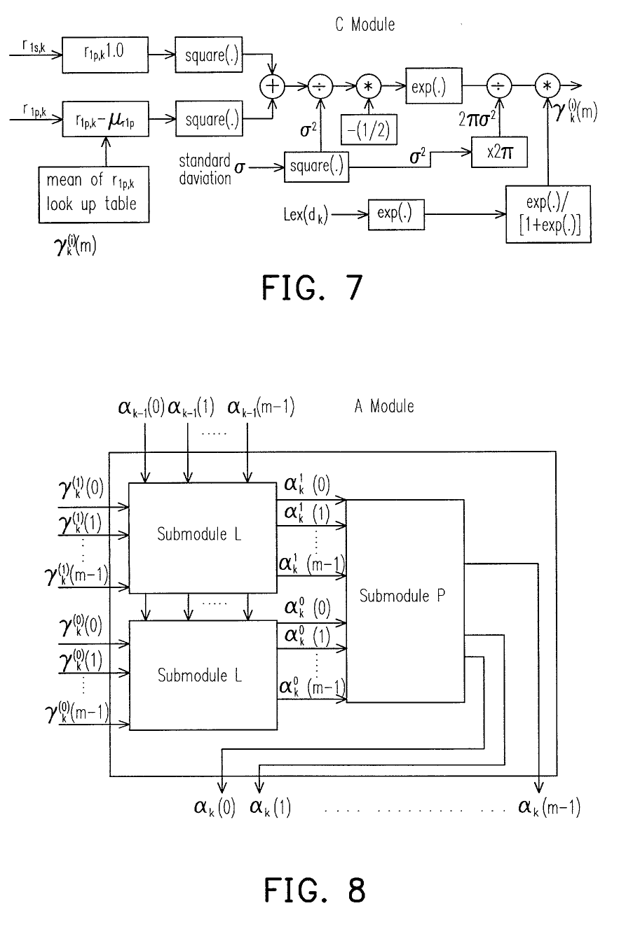

According to the equation (10) and (11), the branch probability parameter γₖ⁽ⁱ⁾(m′,m) can be calculated in parallel. The N+M units of the module C (as shown in FIG. 7) are used to calculate each γₖ⁽ⁱ⁾(m′, m) in parallel. Thus, the N+M units of time can be shortened to a unit of time. The input signal of the module C in FIG. 7 is L_{a,k}, r_{1s,k} and r_{1p,k} respectively, wherein, k=1, . . . , N+M. The module C is used to calculate γₖ⁽¹⁾(m′,m) and γₖ⁽⁰⁾(m′,m) respectively.

In addition, since the forward recursive probability parameter αₖ is output from the previous level to be the input of the next level, and the backward recursive probability parameter βₖ is output from the next level to be the input of the previous level. It is suitable to design as the systolic array VLSI to increase the calculation speed. According to the equation (2), N+M units of Module A (as shown in FIG. 8) are used to calculate αₖ. Wherein, the first level input is γ₁⁽¹⁾(m′,m) and γ₁⁽⁰⁾(m′,m) and the initial value of the forward recursive probability parameter α₀(m) are used to calculate α₁(m). The second level input γ₂⁽¹⁾(m′,m) and γ₂⁽⁰⁾(m′,m) and α₁(m) are used to calculate α₂(m). Thus, the systolic array is able to work simultaneously. All αₖ(m), wherein k=1, . . . , N-M, can be calculated after N+M units of time.

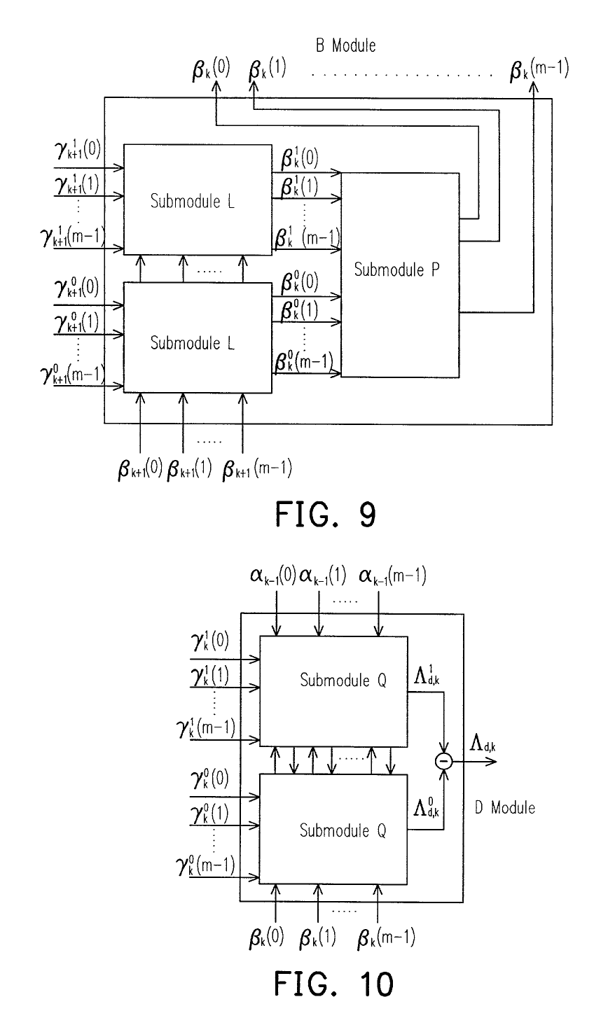

According to the equation (3), it adopts N+M units of Module B (as shown in FIG. 9) for calculating βₖ. Wherein, the first level input is γ_{N+M}⁽¹⁾(m′,m) and γ_{N+M}⁽⁰⁾(m′,m) and the initial value of the backward recursive probability parameter β_{N+M}(m) are used to calculates β_{N+M-1}(m). The inputs of the second level γ_{N+M}⁽¹⁾(m′,m) and γ_{N+M-1}⁽⁰⁾(m′,m), and the backward recursive probability parameters β_{N+M-1}(m) are used to calculate β_{N+M-2}(m). The advantage is the structure of each module is the same; the output of the previous level is the input of the next level. Thus, the throughput is (N+M) times of the original throughput.

When the calculation of αₖ, βₖ and γₖ⁽ⁱ⁾ are completed, according to the equation (1), it adopts N+M units of module D (as the module D shown in FIG. 10) to calculate Λ(dₖ). By using the parallel calculation, the N+M units of time is shortened to a unit of time.

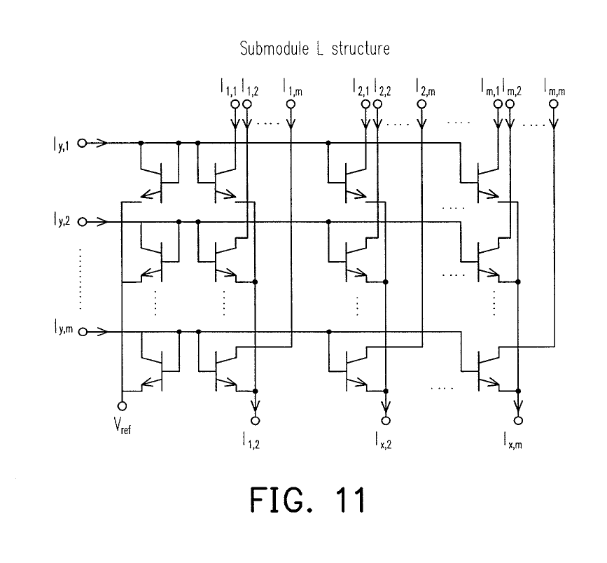

The submodule L located in between the module A and the module B calculates the product-sum of two inputs. As the example shown in FIG. 11, the submodule L adopts the analog circuit provided by the conventional technique. The analog circuits proposed by the reference literatures also can be used. Like H. -A. Loeliger, F. Lustenberger, F. Tarkoy, M. Helfensten, “Decoding in Analog VLSI,” IEEE Communication Magzine, Vol.37 (4), pp.99-101 April 1999, or H. -A. Loeliger, F. Lustenberger, M. Helfensten, F. Tarkoy, “Probability Propagation and Decoding in Analog VLSI,” IEEE Trans.on Information Theory, Vol.47(2), pp.837-843 February 2001, or F. Lustenberger, M. Helfenstein, H, -A, Loeliger, F. Tarkoy, G. S. Moschytz, “An Analog VLSI Decoding Technique for Digital Codes,” ISCAS '99. Proceedings of the 1999 IEEE international Symposium on Circuits and Systems, Vol. 2, pp.424-427 1999, . . . , etc.

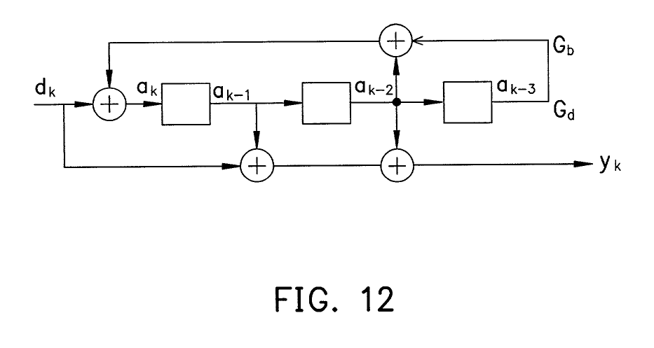

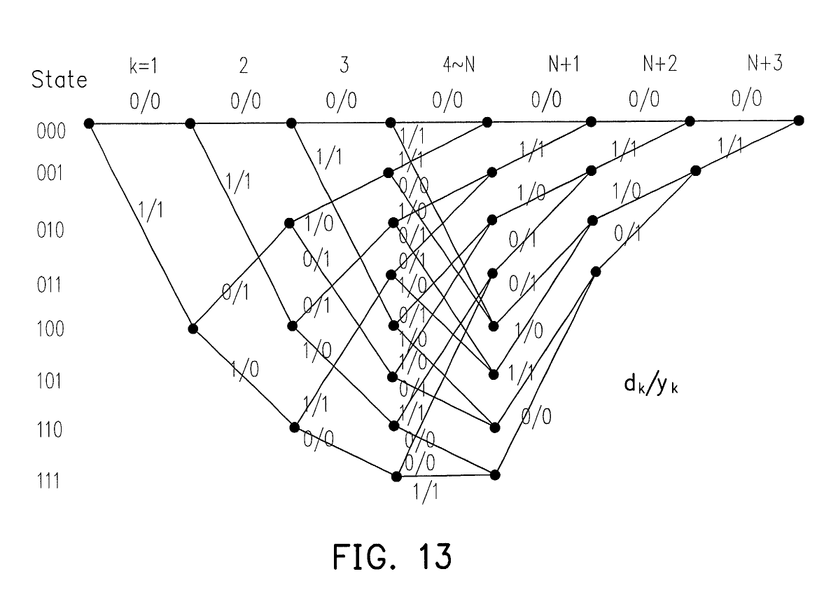

For easy to describe the detail structure of the module A, B, and D mentioned above, the preferred embodiment of the present invention uses the turbo-code of the third generation CDMA mobile communication standard as an example for description. However, it is not used to limit the apply range of the present invention. The turbo-code of the third generation CDMA mobile communication standard is: a decoder register size M=3. For the first decoder and the second decoder, the code ratio R=1/3, the parameter of the feedback generator and the parameter of the direct-feed-forward generator is G_{b}=1011 and G_{d}=1110 respectively. As shown in FIG. 12, the recursive systematic convolution encoder (hereafter abbreviated as RSC), wherein, the RSC adopts the fast RSC encoder, for the physical content of the fast RSC encoder, please refer to the “Fast Turbo-code Encoder” proposed by the same inventor of the present invention in April, 2001. The trellis diagram is shown in FIG. 13.

Referring to the content of FIG. 6, FIG. 6 schematically shows the structure of the simplified modules, data streams, and the latches when the block length N=4 and the register size M=3. There are N+M=7 units of the module A, B, C, and D. In the first unit of time, the parallel input L_{a,k}, r_{1s,k} and r_{1p,k} signals, k=1,2, . . . , 6,7 are used simultaneously to calculate the γ₁⁽ⁱ⁾, γ₂⁽ⁱ⁾, . . . , γ₇⁽ⁱ⁾. In the 7 units of time afterwards, the α₁, α₂, . . . , α₆ and β₁, β₂, . . . , β₆ is calculated respectively. In the other one unit of time afterwards, according to the equation (2), the parallel input γₖ⁽¹⁾(m′,m), γₖ⁽⁰⁾(m′,m), αₖ₋₁ and βₖ₋₁ are used to calculate Λ(dₖ). The Λ(dₖ) is used as the extrinsic parameter of the next level, if the last level is reached, the dₖ is determined accordingly, if dₖ>0, determine dₖ=1, otherwise dₖ=0.

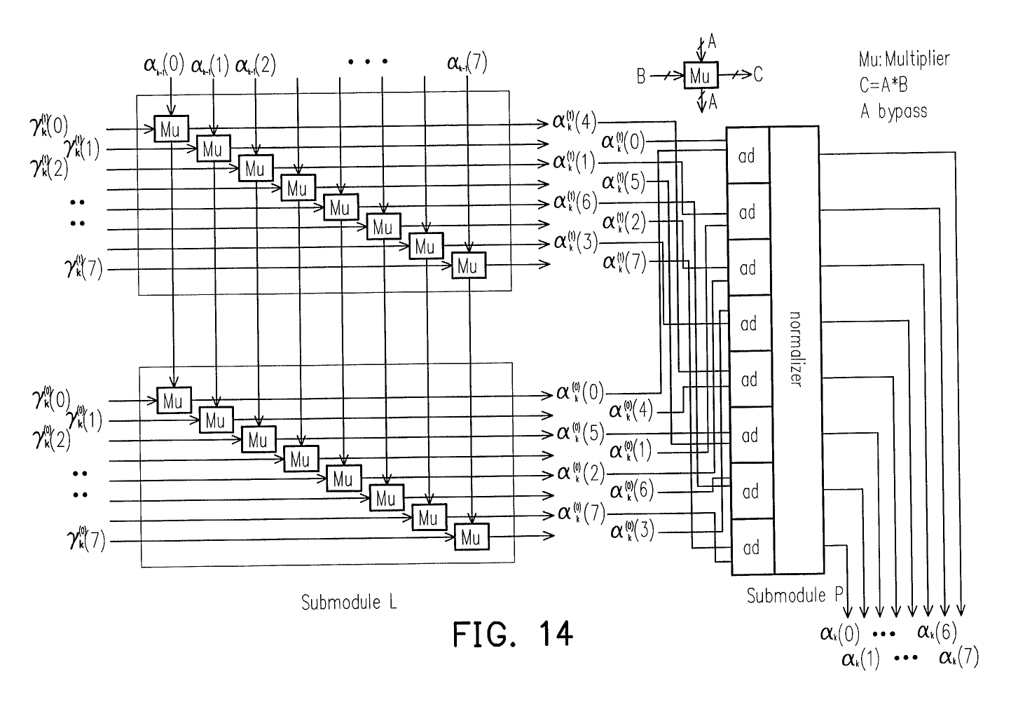

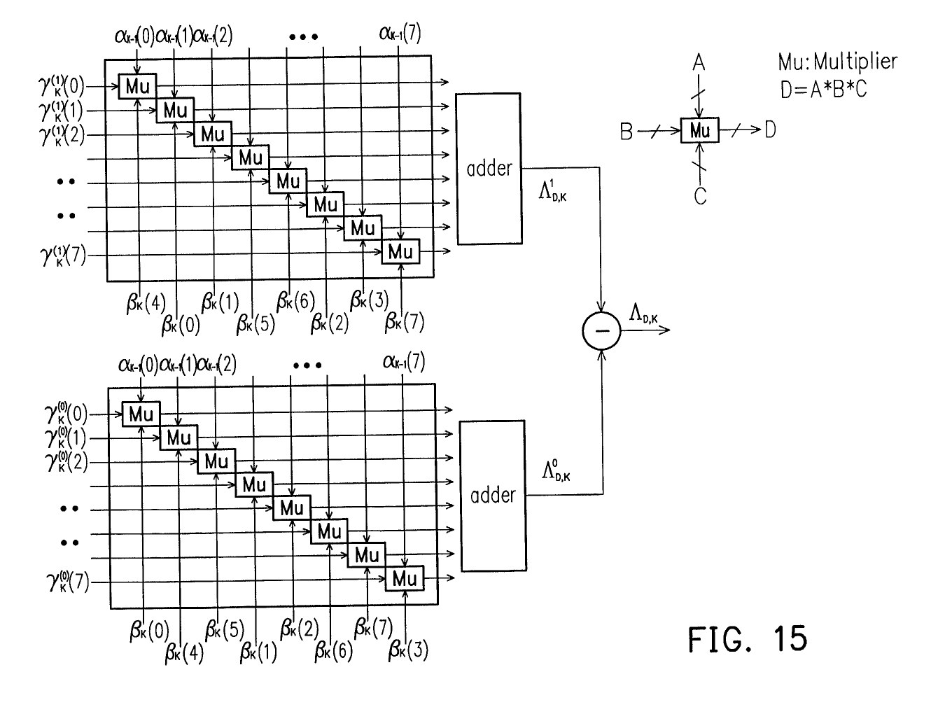

According to the trellis diagram of FIG. 13. It is easy to simplify the structure of the module A, B, and D. FIG. 14 schematically shows the detail structure of the module A based on this design. The detail structure of the module B is also similar to the module A. The detail structure of the module D is shown in FIG. 15.

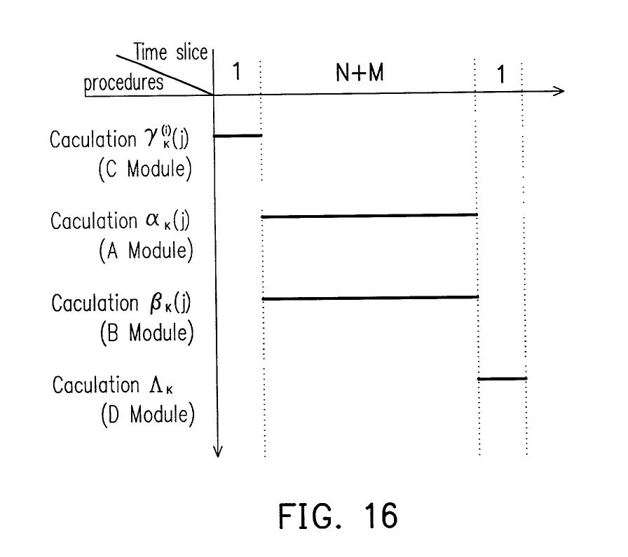

The latency spent for accomplishing a message with one block size length of the parallel and systolic array VLSI structure design of the preferred embodiment according to the present invention, as shown in FIG. 16, is N+M+2 units of time. Comparing to the original conventional sequential calculation structure that needs 5*(N+M) units of time, the time is shortened to about ⅕ only. Furthermore, the systolic array VLSI structure design is able to generate a set of dₖ in every one unit of time after the first set of dₖ is generated.

The performance comparison is shown in table 1:

TABLE 1
The structure comparison of the systolic array and the sequential type

| | | Systolic Array | |
|---|---|---|---|
| Item/Structure | Sequential Structure | Structure | Pro and Con |
| Latency | 5*(N + M) | (N + M) + 2 | The latency is about |
| | | | ⅕ |
| Output Time | 5*(N + M) | 1 | The throughput is |
| | | | about 5*(N + M) |
| | | | times |
| Number of Hardware | 1 | 5*(N + M) | The complexity of |
| Gate | | | the circuit is about |
| | | | 5 *(N + M) times |

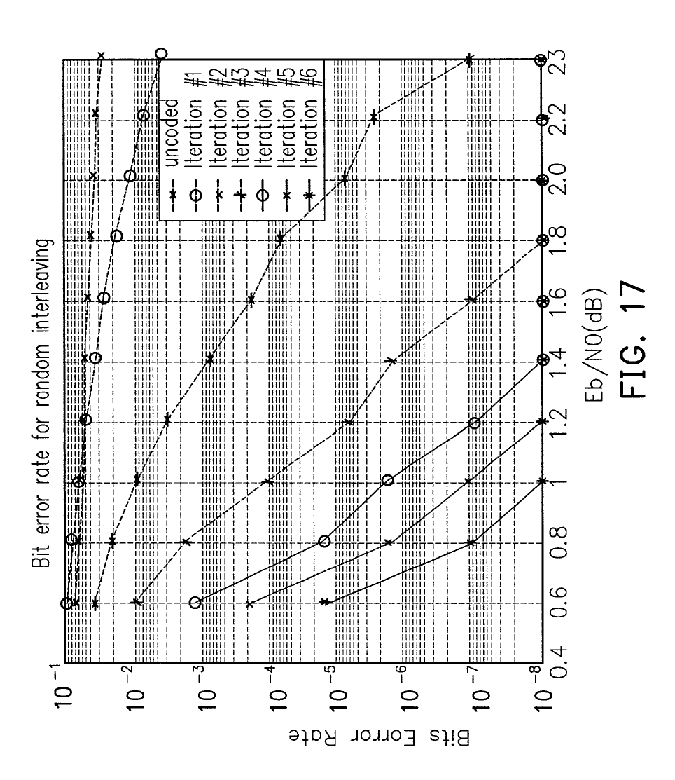

In order to prove the error-correcting feature of the preferred embodiment according to the present invention. Herein, the CDMA mobile communication system mentioned above is used as an example. The RSC decoder with register size M=3 is shown in FIG. 12. The trellis diagram is shown in FIG. 13. The iterative decoding number P=6. The random interleaving method is adopted in between the first decoder and the second decoder. The simulation result is obtained as shown in FIG. 17, wherein, the block length N=65536, the vertical axis is the decoding performance denoted by the bit error rate (BER). The horizontal axis is the communication environment denoted by the signal/noise ratio. As we can see here, under the situation with the same signal/noise ratio, the larger the iterative decoding number, the better the decoding performance. This is accorded with the theory, and is similar to the simulation result disclosed in the contents of the literatures: C. Berrou, A. Glavieux, and P. Thitimajshima, “Near Shannon Limited Error-correcting Coding and Decoding: Turbo-codes (1),” in Proc. ICC'93, May, 1993, and P. Robertson “Illuminating the Structure of Code and Decoder of Parallel Concatenated Recursive Systmatic (Turbo) Codes,” in Proc. IEEE GLOBECOM Conf., San Francisco, Calif. Pp. 1298-1303, December 1994.

The present simulation uses the programming language C language running on the GenuineInter Pentium® III CPU,128 MB RAM personal computer. The simulation runs on the working platform with the Windows Me® operating system. The bit error rate comparison shown in FIG. 17, wherein, the iterative decoding number (p=1, . . . , 6), the code ratio R=1/3, the register size M=3, the generator parameter G_{b}=1011, G_{d}=1110, and uses the 256*256 random interleaving deinterleaving method.

The present invention provides a fast turbo-code decoder. Wherein, the decoder is designed to use the systolic array VLSI circuits. Since the output of previous level can be used as the input of next level. So the advantages of the parallel and the pipeline calculation are totally achieved. The latency is only N+M+2 units of time, the latency is shorten to as about ⅕ comparing to the conventional sequential calculation structure that takes 5*(N+M) units of time. The decoding throughput is about 5*(N+M) times higher than the conventional decoder. Although the quantity of the circuit gate is about 5*(N+M) times higher than the conventional decoder. However, the VLSI techniques had been progressively improved nowadays, thus the hardware complexity is easy to overcome. Devoting the hardware cost to get the higher speed will be a changeless trend.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A turbo-code decoder for communication system, the decoder comprising:
a serial-to-parallel output unit, used to receive a serial input signal and output a parallel signal after converting the serial input signal; and
a plurality of parallel decoding units, wherein the parallel decoding units are serially connected to form a plurality of levels, the first level parallel decoding unit receives the parallel signal that is output from the serial-to-parallel output unit, the output from the first level parallel decoding unit is sent to the second level parallel decoding unit, with certain sequence, the parallel signal passes through the parallel decoding units for decoding process.

2. The turbo-code decoder of claim 1, wherein each of the parallel decoding unit receives an extrinsic parameter when processing the decoding process, to be the signal that is after the decoding process from the parallel decoding unit, and sends the extrinsic parameter to the next level of the parallel decoding unit.

3. The turbo-code decoder of claim 2, wherein the extrinsic parameter is obtained from a deinterleaving operation, the extrinsic parameter of the first level parallel decoding unit is L_{a0,k}=(0, 0 . . . , 0), where k=1, 2, . . . , N, N is the block length of the turbo-code.

4. The turbo-code decoder of claim 1, wherein the serial input signal are r_{1s,k}, r_{1p,k}, and r_{2p,k} messages of the turbo-code, whereas k=1, 2, . . . , N, N is the block length of the turbo-code.

5. The turbo-code decoder of claim 4, wherein the serial-to-parallel output unit receives the r_{1s,k}, r_{1p,k}, and r_{2p,k}, wherein the subscript K=0, 1, . . . , N+M−1 represents the whole block and an end message, wherein M stands for a total number of latch units of the turbo-code decoder, the serial-to-parallel output unit coverts the received r_{1s,k}, r_{1p,k}, and r_{2p,k} messages and outputs results to the first level parallel decoding unit in parallel, the first level parallel decoding unit also receives an extrinsic parameter L_{a,k} at the same time, the parameter L_{a,k} is obtained via a deinterleaving operation on the previous level extrinsic parameter Λ(dₖ), the initial value of the first level decoding unit extrinsic parameter is set as L_{a0,k}=(0, 0 . . . , 0), a first level extrinsic parameter L_{a1,k} is generated via the first level parallel decoding unit, and the message r_{1s,k}, r_{1p,k} and r_{2p,k} pass through sequentially to be the input of the next level.

6. The turbo-code decoder of claim 5, wherein the parallel decoding unit comprises:
a first decoder, used to receive the r_{1s,k}, r_{1p,k} messages and the extrinsic parameter L_{a,k};
a second decoder, used to receive the r_{2p,k} message and the extrinsic parameter L_{a,k};
an interleaving unit, located between the first decoder and the second decoder, used to receive the output of the first decoder; and
a deinterleaving unit, used to connected to the second decoder, alternately outputs the output of the first decoder and the second decoder.

7. The turbo-code decoder of claim 6, wherein the first decoder of the parallel decoding units constitutes a systolic array very large scaled integrated (VLSI) circuits structure.

8. The turbo-code decoder of claim 7, wherein the systolic array VLSI circuits is composed of N+M units of the module C, A, B, D, and E, wherein,
the module C receives L_{a1,k}, r_{1s,k} and r_{1p,k}, and outputs γₖ⁽¹⁾(m′,m) and γₖ⁽⁰⁾(m′,m),
the module A calculates a forward recursive probability parameter αₖ,
the module B calculates a backward recursive probability parameter βₖ,
the module D adopts (N+M) units of parallel calculation to obtain the Λ(dₖ) after the calculation of the αₖ, βₖ, and γₖ⁽ⁱ⁾ are finished, and
the module E outputs the value of the calculation from the module D, where K=1, 2, . . . , N+M.

9. The turbo-code decoder of claim 8, wherein the value of the Λ(dₖ) is calculated according to a MAP algorithm and following equation:
$$Λ ( {d}_{k} ) = log \frac{{\sum }_{m} {\sum }_{{m}^{′}} {γ}_{k}^{( 1 )} ( {m}^{′} , m ) \cdot {α}_{k - 1} ( {m}^{′} ) \cdot {β}_{k} ( m )}{{\sum }_{m} {\sum }_{{m}^{′}} {γ}_{k}^{( 0 )} ( {m}^{′} , m ) \cdot {α}_{k - 1} ( {m}^{′} ) \cdot {β}_{k} ( m )} ,$$
wherein αₖ is the forward recursive probability parameter, βₖ is the backward recursive probability parameter, γₖ⁽ⁱ⁾ is a branch probability parameter.

10. The turbo-code decoder of claim 9, wherein the forward recursive probability parameter αₖ is obtained from the calculation of the previous parameter [symbol]
and the branch probability parameter γₖ⁽ⁱ⁾, the equation is as follows:
$${α}_{k} ( m ) = \frac{{\sum }_{{m}^{′}} {{\sum }^{1}}_{i = 0} {γ}_{k}^{( i )} ( {m}^{′} , m ) \cdot {α}_{k - 1} ( {m}^{′} )}{{\sum }_{m} {\sum }_{{m}^{′}} {{\sum }^{1}}_{i = 0} {γ}_{k}^{( i )} ( {m}^{′} , m ) \cdot {α}_{k - 1} ( {m}^{′} )}$$

11. The turbo-code decoder of claim 9, wherein the backward recursive probability parameter βₖ is obtained from the calculation of the next parameter βₖ₊₁ and the branch probability parameter γₖ₊₁⁽ⁱ⁾ the equation is as follows:
$${β}_{k} ( m ) = \frac{{\sum }_{{m}^{′}} {{\sum }^{1}}_{i = 0} {γ}_{k + 1}^{( i )} ( {m}^{′} , m ) \cdot {β}_{k + 1} ( {m}^{′} )}{{\sum }_{m} {\sum }_{{m}^{′}} {{\sum }^{1}}_{i = 0} {γ}_{k + 1}^{( i )} ( {m}^{′} , m ) \cdot {β}_{k + 1} ( {m}^{′} )}$$

12. The turbo-code decoder of claim 9, wherein the branch probability parameter γₖ⁽ⁱ⁾ is obtained from following equation according to the MAP algorithm:
γₖ⁽ⁱ⁾(m′,m)=p(γ_{1s,k}|dₖ=i,sₖ=m,sₖ₋₁=m′)·p(r_{1s,k}|dₖ=i,sₖ=m,sₖ₋₁=m′)·q(dₖ=i|sₖ=m,sₖ₋₁=m′)·Pr{sₖ=m|sₖ₋₁=m′}
wherein whether the probability parameter q(dₖ=i|sₖ=m,sₖ₋₁=m′) is 0 or 1 depends on the input bit dₖ=i is 0 or 1 combines the probability of the state m′ to the state m.

13. The turbo-code decoder of claim 11, wherein, assuming in a AWGN channel, the probability is calculated as follows:
$$p ( {r}_{1 s , k} \vert {d}_{k} = i , {s}_{k} = m , {s}_{k - 1} = {m}^{′} ) = \frac{1}{\sqrt{2 π} {σ}_{r1s}} exp [ \frac{- {( {r}_{1 s , k} - {μ}_{r1s} )}^{2}}{2 {σ}_{r1s}^{2}} ]$$
$$p ( {r}_{1 p , k} \vert {d}_{k} = i , {s}_{k} = m , {s}_{k - 1} = {m}^{′} ) = \frac{1}{\sqrt{2 π} {σ}_{r1p}} exp [ \frac{- {( {r}_{1 p , k} - {μ}_{r1p} ( {m}^{′} , m ) )}^{2}}{2 {σ}_{r1p}^{2}} ] ,$$
wherein μᵣ₁ₛ and μᵣ₁ₚ(m′,m) is the expectation value of r₁ₛ and r₁ₚ respectively, thereinto, μᵣ₁ₛ depends on the input bit, and μᵣ₁ₚ(m′,m) depends on the input bit and also impacted by the previous state and current state, [symbol]
and σᵣ₁ₚ² is the variant of the r₁ₛ and r₁ₚ respectively.

14. The turbo-code decoder of claim 12, wherein, assuming that the variant of r₁ₛ and r₁ₚ are the same, therefore, the above two equations can be multiplied and consolidated as follows:
$$p ( {r}_{1 s , k} \vert {d}_{k} = i , {s}_{k} = m , {s}_{k - 1} = {m}^{′} ) \cdot \\ p ( {r}_{1 p , k} \vert {d}_{k} = i , {s}_{k} = m , {s}_{k - 1} = {m}^{′} ) = \\ \frac{1}{2 {πσ}^{2}} exp [ \frac{- 1}{2} \frac{{( {r}_{1 s , k} - {μ}_{r1s} )}^{2} + {( {r}_{1 p , k} - {μ}_{r1p} ( {m}^{′} , m ) )}^{2}}{{σ}^{2}} ]$$

15. The turbo-code decoder of claim 11, wherein assuming for a discrete memory-less gauss channel, the branch probability parameter γₖ⁽¹⁾ or γₖ⁽⁰⁾ for input bit being 1 or 0 can be calculated from the equation as follows:
$${γ}_{k}^{( 1 )} ( {m}^{′} , m ) = \frac{1}{2 {πσ}^{2}} exp [ \frac{- 1}{2} \frac{{( {r}_{1 s , k} - 1 )}^{2} + {( {r}_{1 p , k} - {μ}_{r1p} ( {m}^{′} , m ) )}^{2}}{{σ}^{2}} ] \cdot \frac{{e}^{L ( {d}_{K} )}}{1 + {e}^{L ( {d}_{K} )}}$$
$${γ}_{k}^{( 0 )} ( {m}^{′} , m ) = \frac{1}{2 {πσ}^{2}} exp [ \frac{- 1}{2} \frac{{( {r}_{1 s , k} + 1 )}^{2} + {( {r}_{1 p , k} - {μ}_{r1p} ( {m}^{′} , m ) )}^{2}}{{σ}^{2}} ] \cdot \frac{1}{1 + {e}^{L ( {d}_{K} )}} \\$$

16. The turbo-code decoder of claim 5, wherein the N=4 and the register size M=3, the simplified modules, a data stream, and a latch structure are shown as the content of FIG. 6.

17. The turbo-code decoder of claim 5, wherein the a priori probability of the input bit dₖ calculated by the previous level parallel decoding unit can be used by the next level decoder.

18. The turbo-code decoder of claim 5, wherein L(dₖ) is the log likelihood ratio (LLR) extrinsic parameter calculated from the message bit dₖ by the previous level decoder.
